(19) United States
(12) Patent Application Publication
(10) Pub. No.: US 2026/0333981 A1
(43) Pub. Date: Oct. 22, 2026

(54) LED LIGHT SOURCE WITH A COATING CLADDING LAYER

(71) Applicant: SAVANT TECHNOLOGIES LLC, East Cleveland, OH (US)

(72) Inventors: Xuda LI, Shanghai (CN); Jie GAO, Shanghai (CN); Kun XIAO, Shanghai (CN)

(73) Assignee: SAVANT TECHNOLOGIES LLC, East Cleveland, OH (US)

(21) Appl. No.: 19/634,995

(22) Filed: Mar. 31, 2026

(30) Foreign Application Priority Data
Mar. 31, 2025 (CN) 202510396984.8

(51) Int. Cl. H10H 29/851; H10H 29/01; H10H 29/854

(52) U.S. Cl. CPC H10H 29/8512; H10H 29/0361; H10H 29/854

(57) ABSTRACT

Provided is an LED light source with a coating cladding layer that includes a substrate, one or more LED chips formed on the substrate, a phosphor material underlying layer covering the LED chip and exhibiting a first color in a non-illuminated state of the LED chip, and an outer coating covering the outer side of the phosphor material underlying layer and comprising functional particles, the functional particles are selected from a pearlescent pigment and/or mica powder, and the outer coating causes the LED light source to exhibit a second color different from the first color in the non-illuminated state of the LED chip.

### CROSS-REFERENCE TO RELATED APPLICATION

This application claims priority to Chinese Patent Application Serial Number 202510396984.8, filed Mar. 31, 2025, which is herein incorporated by reference.

### DESCRIPTION

### Technical Field

The present invention relates to an LED light source with a coating cladding layer, and more particularly, to an LED light source having an outer coating comprising a pearlescent pigment and/or mica powder, and a lighting device comprising the LED light source.

### Background

Lighting devices, such as lamps, illuminators, decorative or general purpose lamps, electronic tubes or other light emitting devices or other lighting systems, typically comprise one or more light emitting diode (LED) light sources (filaments) consisting of a linear series of LED chips arranged on a transparent substrate that are supported or retained in an enclosure to provide the appearance of incandescent lamps. The light sources (filaments) are typically constructed from InGaN blue-emitting LED die carried on a substantially linear glass or sapphire substrate and covered or encapsulated with a mixture of silicone and phosphor. In general, the encapsulating mixture can have a yellow color or other color in a non-illuminated state. An exemplary LED filament with a yellow colored covering is shown in FIG. 1A. The appearance of this filament may be unfavorable due to objections to the yellow color in the non-illuminated state (especially when used in decorative and general purpose lamps). In practical commercial LED products, silica gel is generally used as a raw material for preparing an outer coating, which results in a large thickness of the coating, although the color is changed, the appearance is adversely affected due to the increase of the thickness.

### SUMMARY

A main object of the present invention is to provide an LED light source with an outer coating and having an aesthetic appearance and a high light transmittance, so as to solve the problem in the prior art.

In order to achieve the above object, in one aspect, the present invention provides an LED light source, comprising: a substrate; one or more LED chips formed on the substrate; a phosphor material underlying layer covering the LED chip and exhibiting a first color in a non-illuminated state of the LED chip; and an outer coating covering the outer side of the phosphor material underlying layer and comprising functional particles, wherein the functional particles are selected from a pearlescent pigment and/or mica powder, and the outer coating causes the LED light source to exhibit a second color different from the first color in the non-illuminated state of the LED chip.

In order to achieve the above object, in another aspect, the present invention further provides a lighting device comprising one or more LED light sources and a driving device, the LED light source comprising: a substrate; one or more LED chips formed on the substrate; a phosphor material underlying layer covering a light emitting surface of the LED chip and exhibiting a first color in a non-illuminated state of the LED chip; and an outer coating covering the outer side of the phosphor material underlying layer and comprising functional particles, wherein the functional particles are selected from a pearlescent pigment and/or mica powder, and the outer coating causes the LED light source to exhibit a second color different from the first color in the non-illuminated state of the LED chip.

Further, the phosphor material underlying layer comprises a phosphor material and an encapsulating glue.

Further, the encapsulating glue comprises one or more of a silica gel, a silicone resin, an epoxy resin, or an acrylate resin, and has a light transmittance of ≥85% after curing.

Further, the particle size D50 of the functional particle is <50 μm.

Further, the pearlescent pigment comprises one or more of mica-based, glass-based, aluminum-based, metal oxide-based, or organic-based pearlescent pigments.

Further, the mica powder has an aspect ratio of ≥10, and comprises one or more of muscovite, sericite, phlogopite, or fluorophlogopite.

Further, the second color is white, silver, gold, red, purple, green, blue, gray, black, or a mixed color or gradient color thereof.

Further, the second color is achieved by the following functional particles: silver: a titanium dioxide-coated mica flake pearlescent pigment having a particle size D50 of <30 μm; gold: an iron oxide-coated mica flake pearlescent pigment having a particle size D50 of <30 μm; and other colorful colors or gradient colors thereof: composite particles of mica powder and dye having a particle size D50 of <20 μm.

Further, the outer coating causes the LED light source to exhibit a pearlescent appearance in a non-illuminated state of the LED chip.

Further, the outer coating further comprises an encapsulating glue, and the mass ratio of the functional particles in the encapsulating glue is greater than or equal to 0.1% and less than 10%.

Further, the encapsulating glue comprises one or more of silica gel, a silicone resin, an epoxy resin, and an acrylate resin, and has a light transmittance of ≥85% after curing.

Yet another aspect of the present invention provides use of a pearlescent pigment and/or mica powder in preparing an outer coating of an LED light source, wherein the LED light source comprises one or more LED chips, the LED chip is covered with a phosphor material underlying layer, and the outer coating covers the outer side of the phosphor material underlying layer; the phosphor material underlying layer exhibits a first color in a non-illuminated state of the LED chip, and the outer coating causes the LED light source to exhibit a second color different from the first color in the non-illuminated state of the LED chip.

Further, the phosphor material underlying layer exhibits a yellow, orange, or red appearance.

Further, the phosphor material underlying layer comprises a doped phosphor having a fluoride host.

Further, the phosphor material underlying layer comprises a phosphor material that comprises a PFS phosphor (K₂SiF₆:Mn₄₊).

Further, the phosphor material underlying layer comprises a yellow or green light emitting phosphor, such as a garnet phosphor.

Further, the phosphor material underlying layer comprises a red light emitting phosphor, such as a Eu2+ red nitride phosphor.

Further, the phosphor material underlying layer comprises an absorbing agent.

Further, the phosphor material underlying layer comprises a resin material.

The present invention provides an LED light source, comprising: a substrate; one or more LED chips formed on the substrate; a phosphor material underlying layer covering the LED chip and exhibiting a first color in a non-illuminated state of the LED chip; and an outer coating covering the outer side of the phosphor material underlying layer and comprising functional particles, wherein the functional particles are selected from a pearlescent pigment and/or mica powder, and the outer coating causes the LED light source to exhibit a second color different from the first color in the non-illuminated state of the LED chip.

According to some embodiments, the phosphor material underlying layer comprises a phosphor material and an encapsulating glue.

According to some embodiments, the encapsulating glue comprises one or more of silica gel, a silicone resin, an epoxy resin, or an acrylate resin, and has a light transmittance of ≥85% after curing.

According to some embodiments, the functional particles have a particle size D50 of <50 μm.

The pearlescent pigment comprises one or more of mica-based, glass-based, aluminum-based, metal oxide-based, or organic-based pearlescent pigments.

The mica powder has an aspect ratio of ≥10 and comprises one or more of muscovite, sericite, phlogopite, or fluorophlogopite.

The second color is white, silver, gold, red, purple, green, blue, gray, black, or a mixed color or gradient color thereof.

The second color is achieved by the following functional particles: silver: a titanium dioxide-coated mica flake pearlescent pigment having a particle size D50 of <30 μm; gold: an iron oxide-coated mica flake pearlescent pigment having a particle size D50 of <30 μm; and other colorful colors or gradient colors thereof: composite particles of mica powder and dye having a particle size D50 of <20 μm.

The outer coating causes the LED light source to exhibit a pearlescent appearance in the non-illuminated state of the LED chip.

The outer coating further comprises an encapsulating glue, and the mass ratio of the functional particles in the encapsulating glue is greater than or equal to 0.1% and less than 10%.

The encapsulating glue comprises one or more of silica gel, a silicone resin, an epoxy resin, and an acrylate resin, and has a light transmittance of ≥85% after curing.

According to one embodiment, a lighting device comprising one or more LED light sources and a driving device, the LED light source comprising: a substrate; one or more LED chips formed on the substrate; a phosphor material underlying layer covering a light emitting surface of the LED chip and exhibiting a first color in a non-illuminated state of the LED chip; and an outer coating covering the outer side of the phosphor material underlying layer and comprising functional particles, wherein the functional particles are selected from a pearlescent pigment and/or mica powder, and the outer coating causes the LED light source to exhibit a second color different from the first color in the non-illuminated state of the LED chip.

The phosphor material underlying layer comprises a phosphor material and an encapsulating glue.

The encapsulating glue comprises one or more of silica gel, a silicone resin, an epoxy resin, or an acrylate resin, and has a light transmittance of ≥85% after curing.

The functional particles have a particle size D50 of <50 μm.

The pearlescent pigment comprises one or more of mica-based, glass-based, aluminum-based, metal oxide-based, or organic-based pearlescent pigments.

The mica powder has an aspect ratio of ≥10 and comprises one or more of muscovite, sericite, phlogopite, or fluorophlogopite.

The second color is white, silver, gold, red, purple, green, blue, gray, black, or a mixed color or gradient color thereof.

The second color is achieved by the following functional particles: silver: a titanium dioxide-coated mica flake pearlescent pigment having a particle size D50 of <30 μm; gold: an iron oxide-coated mica flake pearlescent pigment having a particle size D50 of <30 μm; and other colorful colors or gradient colors thereof: composite particles of mica powder and an organic dye having a particle size D50 of <20 μm.

The outer coating causes the LED light source to exhibit a pearlescent appearance in the non-illuminated state of the LED chip.

The outer coating further comprises an encapsulating glue, and the mass ratio of the functional particles in the encapsulating glue is greater than or equal to 0.1% and less than 10%.

The encapsulating glue comprises one or more of silica gel, a silicone resin, an epoxy resin, or an acrylate resin, and has a light transmittance of ≥85% after curing.

Use of a pearlescent pigment and/or mica powder in preparing an outer coating of an LED light source, wherein the LED light source comprises one or more LED chips, the LED chip is covered with a phosphor material underlying layer, and the outer coating covers the outer side of the phosphor material underlying layer; the phosphor material underlying layer exhibits a first color in a non-illuminated state of the LED chip, and the outer coating causes the LED light source to exhibit a second color different from the first color in the non-illuminated state of the LED chip.

In the technical solution of the present invention, by means of the outer coating comprising a pearlescent pigment and/or mica powder of the present invention, the appearance of the LED light source can be changed from the yellow appearance of the phosphor underlying layer to an appearance of other colors, even a gradient color and a mixed color, and a pearlescent effect is exhibited, thereby improving the aesthetic appearance of the LED light source. In addition, the outer coating comprising the pearlescent pigment and/or mica powder of the present invention is chemically stable, thus being environmentally friendly and not easy to cause pollution during production and use.

### BRIEF DESCRIPTION OF THE DRAWINGS

The accompanying drawings, which form a part of the present application, are used to provide a further understanding of the present invention. The schematic examples of the present invention and the description thereof are used to explain the present invention, and do not form improper limits to the present invention. In the drawings:

FIG. 1A is a schematic diagram showing the structure of an LED filament having a colored covering in the prior art.

FIG. 1B is a schematic diagram showing the structure of an LED light source having an outer coating coated on a phosphor material underlying layer according to an embodiment of the present disclosure.

FIG. 1C is a schematic diagram showing the appearance of an LED filament having a colored covering in the prior art in a non-illuminated state.

FIG. 1D is a schematic diagram showing the appearance of an LED light source coated with an outer coating on a phosphor material underlying layer in a non-illuminated state according to an embodiment of the present disclosure.

FIG. 2 shows exemplary LED light sources having a variety of color appearances according to disclosed embodiments.

FIG. 3 shows a schematic view of a lighting device having an LED filament.

FIG. 4 shows photoelectric parameters of the LED filaments according to disclosed embodiments.

### DETAILED DESCRIPTION OF THE EMBODIMENTS

It should be noted that the examples and features in the examples in the application can be combined with each other without conflicting. The present invention will be described in detail below in combination with embodiments.

Although the disclosed embodiments will be described with reference to the embodiments shown in the drawings and described below, it should be understood that these embodiments may be embodied in many alternate forms. In addition, any suitable size, shape, or type of element or material may be used.

As discussed above, LED light sources having an outer coating in the prior art suffer from high thickness, poor aesthetics, and low light transmission. Based on the described problems, the present disclosure provides an LED light source having an outer coating. By using an outer coating comprising a pearlescent pigment and/or mica powder, an LED light source having an excellent appearance can be provided. The outer coating changes the appearance of the LED light source from a colored appearance (e.g., yellow appearance) of the phosphor material underlying layer to an appearance of other colors (e.g., the outer coating causes the LED light source to exhibit a white, silver, gold, red, purple, green, blue, gray, black, mixed or gradient color appearance thereof in a non-illuminated state) and to exhibit a pearlescent appearance in the non-illuminated state of the LED light source while maintaining an acceptable level of performance.

One or more embodiments relate to an LED filament, comprising one or more LED chips, wherein the LED chip is coated with a phosphor material underlying layer exhibiting a colored appearance; and an outer coating on the outer side of the phosphor material underlying layer, the outer coating comprising a pearlescent pigment and/or mica powder. The phosphor material underlying layer exhibits a first color in a non-illuminated state of the LED chip, and the outer coating causes the LED filament to exhibit a second color different from the first color in the non-illuminated state of the LED chip.

The phosphor material underlying layer comprises a phosphor material. The phosphor material comprises fluorescent powder doped with rare earth ions, and is covered on a light-emitting surface of the LED chip after being mixed with an encapsulating glue.

The outer coating comprises an encapsulating glue and functional particles dispersed in the encapsulating glue, and the functional particles are selected from a pearlescent pigment and/or mica powder. “Underlying layer” generally refers to a layer of a phosphor material that exhibits a colored (e.g., yellow) appearance, which is located beneath the outer coating. That is, the underlying layer is positioned between the outer coating and the LED chip. There may or may not be an intermediate layer between the LED chip and the underlying layer, and/or between the underlying layer and the outer coating. Generally, in this disclosure, reference to a “colored” or “white” appearance relates to the color of a material when not excited by an excitation wavelength. For example, if the underlying layer comprises only phosphor powder that is white powder when observed under non-exciting visible light, it may not be considered “colored” even though it may exhibit a color when excited to emit light.

Another specific embodiment of the present disclosure provides a lighting device, comprising one or more LED light sources, wherein the LED light source comprises: a substrate, and one or more LED chips formed on the substrate, wherein the LED chip is coated with a phosphor material underlying layer exhibiting a colored appearance; and an outer coating on an outer side of the phosphor material underlying layer, and the outer coating comprising a pearlescent pigment and/or mica powder.

As described above, in the lighting device according to the present invention, the LED light source having the outer coating comprising the pearlescent pigment and/or mica powder is used, and by using the outer coating comprising the pearlescent pigment and/or mica powder, an LED light source having an excellent appearance can be provided. The outer coating changes the appearance of the LED light source from a colored appearance (e.g., yellow appearance) of the phosphor material underlying layer to an appearance of other colors (e.g., the outer coating causes the LED light source to exhibit a white, silver, gold, red, purple, green, blue, gray, black, mixed or gradient color appearance thereof in a non-illuminated state) and to exhibit a pearlescent appearance in the non-illuminated state of the LED light source while maintaining an acceptable level of performance.

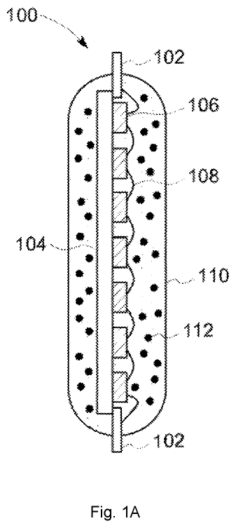

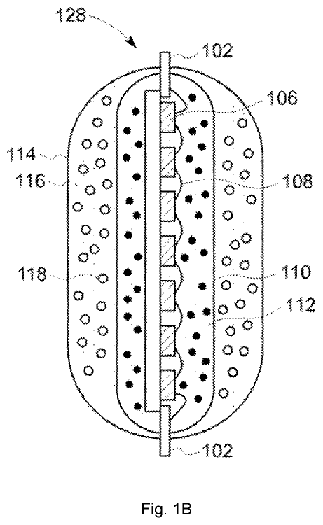

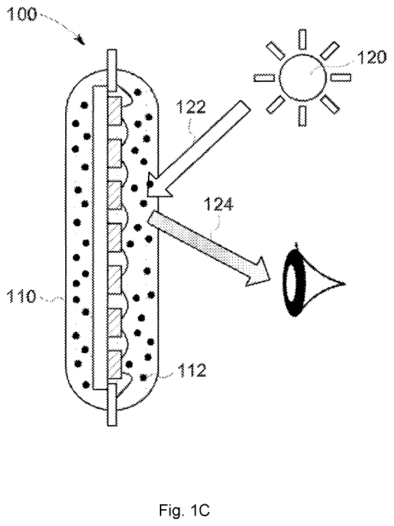

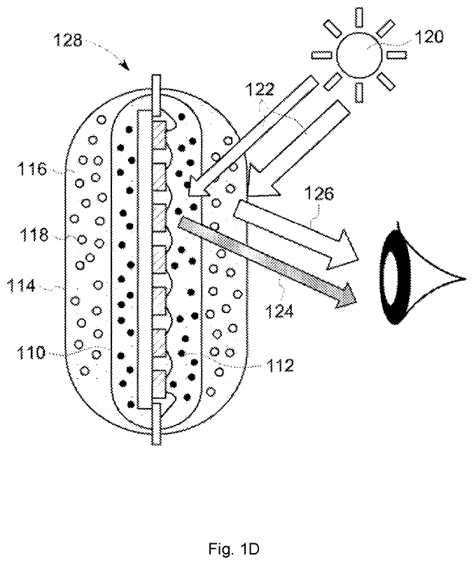

FIG. 1A shows the structure of a conventional LED filament 100. Metal leads 102 are generally connected to a substrate 104 on which a series of LED dies 106 are mounted. Metal leads 102 and LED dies 106 are electrically coupled by wire bonds 108 and the components are packaged using a underlying layer 110, which generally comprises phosphor particles 112. As shown in FIG. 1B, the LED filament may be overcoated with a layer 114 to provide an LED filament 128, wherein the layer 114 comprises a resin material 116 loaded with a pearlescent pigment and/or mica powder 118. FIGS. 1C and 1D depict the difference in appearance of the LED filament 100 and 128 in a non-illuminated state. Referring to FIG. 1C, a light source 120, such as sunlight, provides white light 122 that irradiates on the underlying layer 110. The phosphor particles 112 absorb the blue portion of the incident light and reflect the non-absorbed portion 124, resulting in a yellow appearance. Turning to FIG. 1D, the light source 120 also provides white light 122, however, most of the white light is reflected or scattered by the outer coating 114 of the resin material 116 loaded with the pearlescent pigment and/or mica powder 118. Only a portion of the light 122 passes through the outer coating 114 and is reflected from the underlying layer 110. The light 126 reflected from the outer coating 114 exhibits the color of the pearlescent pigment and/or mica powder, while the light 124 reflected from the underlying layer 110 is yellow, but because only a portion of the light 122 is reflected from the underlying layer 110, the apparent color of the LED filament 128 differs from the traditional LED filament 100. Due to the unique optical effect of the pearlescent pigment and/or mica powder, the LED filament 128 further exhibits a pearlescent effect in addition to exhibiting different appearance colors, and effects such as a gradient color and mixed color can be achieved.

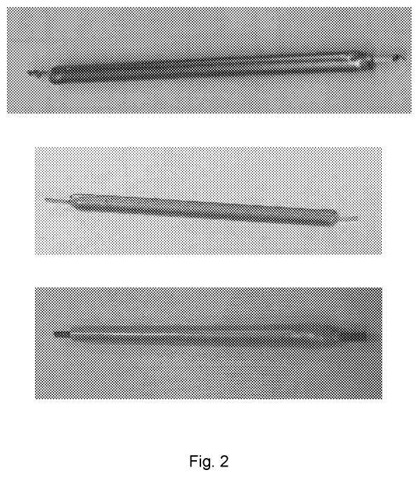

FIG. 2 shows exemplary LED light sources having a variety of color appearances according to disclosed embodiments.

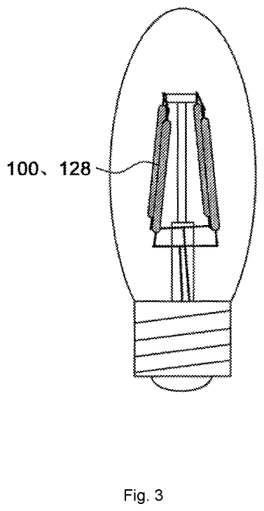

FIG. 3 shows a schematic diagram of a lighting device having a LED filament (100 or 128).

In some examples, the light source may include one or more of a filament, a lamp bead, a light strip, and a light sheet.

In some examples, the outer coating further comprises an encapsulating glue of a resin material. The resin material of the outer coating can comprise a polymer, such as a silicone resin, an epoxy resin, and an acrylate resin. The properties of the resin material may be matched to the features of the underlying layer to minimize the stress and optical interference loss at the interface between the resin material and the underlying layer. In one or more embodiments, the resin material of the outer coating can have a refractive index that at least approximates or substantially matches the refractive index of the underlying layer. In some embodiments, the resin material can have a refractive index ranging from about 1.4 to 1.6. In some embodiments, the resin material can have a coefficient of thermal expansion that approximates or substantially matches the coefficient of thermal expansion of the underlying layer. An exemplary thermal expansion coefficient of the resin material can be 310 μm/m−°C. In one or more embodiments, the resin material can have one or more of the same mechanical, thermal, optical, electrical, or any other suitable properties as the underlying layer. In some embodiments, the resin material can be the same as the resin material used for the underlying layer. An example of the resin coating can be a two-component polydimethylsiloxane elastomer. A person skilled in the art would have been able to select a specific resin material and possible other reagents (such as a solvent and an additive) according to desired specific optical and mechanical properties of the outer coating and adjust the amount of the resin material used.

In some examples, the pearlescent pigment comprises one or more of mica-based pearlescent pigments, glass-based pearlescent pigments, aluminum-based pearlescent pigments, metal oxide pearlescent pigments, and organic pearlescent pigments.

In some examples, the mica powder comprises one or more of muscovite, sericite, phlogopite, and fluorophlogopite.

Any known pearlescent pigment and/or mica powder can be used in the outer coating as long as the outer coating can change the appearance of the LED light source from the colored appearance (e.g., yellow appearance) of the phosphor material underlying layer to the appearance of other colors. A person skilled in the art would have been able to select a specific pearlescent pigment and/or mica powder according to a specific appearance and color of a desired LED light source.

In some examples, the phosphor material underlying layer exhibits a yellow, orange, or red appearance. In particular, the phosphor material underlying layer can comprise a doped phosphor having a fluoride host. For example, the phosphor material underlying layer can comprise a phosphor material that comprises a PFS phosphor (K₂SiF₆:Mn₄₊). Additionally, the phosphor material underlying layer can comprise a yellow or yellow-green light emitting phosphor, such as a garnet phosphor, or can comprise a red emitting phosphor, such as a Eu2+ red nitride phosphor.

In some examples, the phosphor material underlying layer can comprise an absorbing agent and/or a resin material.

The outer coating can be applied to a conventional LED light source by various processes, for example, spraying, molding, dipping, application by an automated or manual fluid dispenser, or any other suitable application process. In addition, a person skilled in the art, on the basis of the present disclosure combined with common general knowledge in the art, would have been able to select a specific process and material for preparing an LED light source, a phosphor material underlying layer and an outer coating according to actual needs.

### Example 1

A substrate and LED chips were provided, and the LED chips were mounted on the substrate to form an LED die with the LED chip arranged on the substrate. A phosphor material underlying layer was coated on the LED die. The phosphor material underlying layer was prepared by mixing a Mn4+ activated complex fluoride phosphor (K2SiF6:Mn4+) and an epoxy encapsulating glue. An LED filament having the phosphor material underlying layer was thus obtained.

For the described LED filament having the phosphor material underlying layer, a titanium dioxide-coated mica flake pearlescent pigment having a particle size D50 of <30 μm and an epoxy resin encapsulating glue were mixed to prepare an outer coating, and the outer coating was coated onto the described phosphor material underlying layer to form an outer coating on the phosphor material underlying layer. An LED filament with an external coating was thus obtained. The concentration of the pearlescent pigment in the encapsulating glue was 0.9 wt %.

### Example 2

An LED filament having a phosphor material underlying layer and an LED filament having an outer coating were prepared according to the same method as that in Example 1, except that the concentration of the pearlescent pigment in the encapsulating glue was 1.0 wt %.

### Example 3

An LED filament having a phosphor material underlying layer and an LED filament having an outer coating were prepared according to the same method as that in Example 1, except that the concentration of the pearlescent pigment in the encapsulating glue was 1.1 wt %.

### Example 4

An LED filament having a phosphor material underlying layer and an LED filament having an outer coating were prepared according to the same method as that in Example 1, except that the concentration of the pearlescent pigment in the encapsulating glue was 1.2 wt%.

### Example 5

An LED filament having a phosphor material underlying layer and an LED filament having an outer coating were prepared according to the same method as that in Example 1, except that the concentration of the pearlescent pigment in the encapsulating glue was 10 wt %.

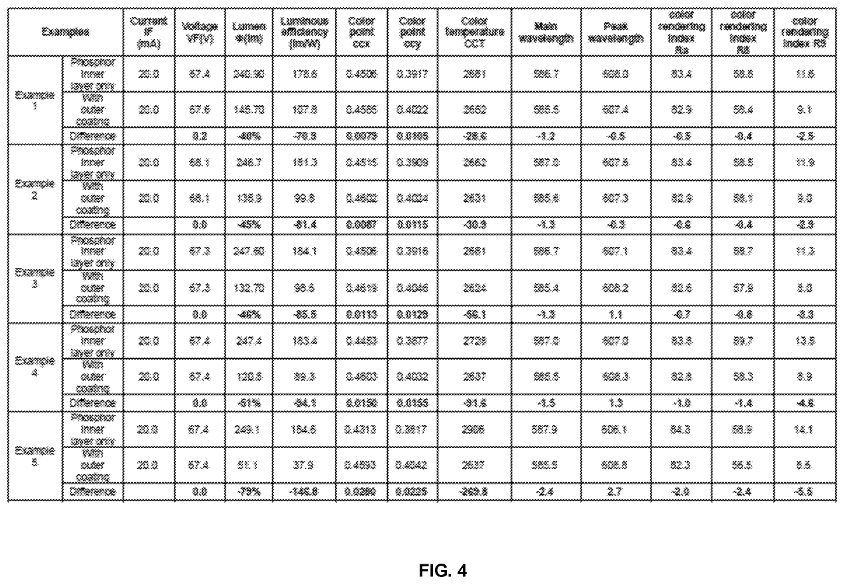

The photoelectric parameters of the LED filaments prepared in Examples 1-5 were measured, including luminous current and voltage, lumen, luminous efficiency, color (color point, color temperature, wavelength), and color rendering index (Ra, R8, R9), and are listed in the table shown in FIG. 4

It can be determined from the data in the table above that after an outer coating comprising a pearlescent pigment and/or mica powder is added to an LED filament having a phosphor material underlying layer, the photoelectric parameters of the LED filament are substantially consistent except that the lumen (brightness) is slightly lost. That is, the LED filament after application of the outer coating can still emit light source colors and qualities similar to those before application of the outer coating. Therefore, the LED filament of the present invention provides more exterior colors without substantially changing the luminous performance of the original LED filament.

It can also be determined from the data in the table above that the higher the concentration of pearlescent pigment and/or mica powder in the outer coating, the greater the lumen loss. However, moreover, a higher concentration is beneficial for obtaining a better appearance color, and therefore for the concentration of the pearlescent pigment and/or mica powder in the outer coating, there is need to consider the balance of the described two parameters. For example, when the concentration of the pearlescent pigment and/or mica powder is 10%, the lumen loss is found to be large, and thus a concentration of the pearlescent pigment and/or mica powder of greater than or equal to 0.1% and less than 10% is advantageous for obtaining a better balance of lumen loss and appearance color.

It should be noted that the embodiments described herein can be used alone or in any combination thereof. It should be understood that the foregoing description is merely illustrative of embodiments. Various alternatives and modifications can occur to a person skilled in the art without departing from the embodiments. Therefore, it is intended that the embodiments of the present invention cover all such alternatives, modifications and variations falling within the scope of the appended claims.

Various modifications and adaptations will become apparent to a person skilled in the relevant arts in view of the foregoing description, when read in conjunction with the accompanying drawings. However, all such and similar modifications taught by the disclosed embodiments will still fall within the scope of the disclosed embodiments.

The various features of the different embodiments described herein can be interchanged with one another. In accordance with the principles of the present disclosure, various described features as well as any known equivalents can be mixed and matched to construct additional embodiments and techniques.

In addition, some features of the exemplary embodiments can be advantageously used without corresponding use of other features. Accordingly, the foregoing description should be considered as illustrative only of the principles of the disclosed embodiments and not in limitation thereof.

1. An LED light source, comprising:
a substrate;
one or more LED chips formed on the substrate;
a phosphor material underlying layer covering the LED chip and exhibiting a first color in a non-illuminated state of the LED chip; and
an outer coating covering the outer side of the phosphor material underlying layer and comprising functional particles, wherein the functional particles are selected from a pearlescent pigment and/or mica powder, and the outer coating causes the LED light source to exhibit a second color different from the first color in the non-illuminated state of the LED chip.

2. The LED light source of claim 1, wherein the phosphor material underlying layer comprises a phosphor material and an encapsulating glue.

3. The LED light source of claim 2, wherein the encapsulating glue comprises one or more of silica gel, a silicone resin, an epoxy resin, or an acrylate resin, and has a light transmittance of ≥85% after curing.

4. The LED light source of claim 1, wherein the functional particles have a particle size D50 of <50 μm.

5. The LED light source of claim 1, wherein the pearlescent pigment comprises one or more of mica-based, glass-based, aluminum-based, metal oxide-based, or organic-based pearlescent pigments.

6. The LED light source of claim 1, wherein the mica powder has an aspect ratio of ≥10 and comprises one or more of muscovite, sericite, phlogopite, or fluorophlogopite.

7. The LED light source of claim 1, wherein the second color is white, silver, gold, red, purple, green, blue, gray, black, or a mixed color or gradient color thereof.

8. The LED light source of claim 7, wherein the second color is achieved by the following functional particles:
silver: a titanium dioxide-coated mica flake pearlescent pigment having a particle size D50 of <30 μm;
gold: an iron oxide-coated mica flake pearlescent pigment having a particle size D50 of <30 μm; and
other colorful colors or gradient colors thereof: composite particles of mica powder and dye having a particle size D50 of <20 μm.

9. The LED light source of claim 1, wherein the outer coating causes the LED light source to exhibit a pearlescent appearance in the non-illuminated state of the LED chip.

10. The LED light source of claim 1, wherein the outer coating further comprises an encapsulating glue, and the mass ratio of the functional particles in the encapsulating glue is greater than or equal to 0.1% and less than 10%.

11. The LED light source of claim 10, wherein the encapsulating glue comprises one or more of silica gel, a silicone resin, an epoxy resin, and an acrylate resin, and has a light transmittance of ≥85% after curing.

12. A lighting device comprising one or more LED light sources and a driving device, the LED light source comprising:
a substrate;
one or more LED chips formed on the substrate;
a phosphor material underlying layer covering a light emitting surface of the LED chip and exhibiting a first color in a non-illuminated state of the LED chip; and
an outer coating covering the outer side of the phosphor material underlying layer and comprising functional particles, wherein the functional particles are selected from a pearlescent pigment and/or mica powder, and the outer coating causes the LED light source to exhibit a second color different from the first color in the non-illuminated state of the LED chip.

13. The lighting device of claim 12, wherein the phosphor material underlying layer comprises a phosphor material and an encapsulating glue.

14. The lighting device of claim 13, wherein the encapsulating glue comprises one or more of silica gel, a silicone resin, an epoxy resin, or an acrylate resin, and has a light transmittance of ≥85% after curing.

15. The lighting device of claim 12, wherein the functional particles have a particle size D50 of <50 μm.

16. The lighting device of claim 12, wherein the pearlescent pigment comprises one or more of mica-based, glass-based, aluminum-based, metal oxide-based, or organic-based pearlescent pigments.

17. The lighting device of claim 12, wherein the mica powder has an aspect ratio of ≥10 and comprises one or more of muscovite, sericite, phlogopite, or fluorophlogopite.

18. The lighting device of claim 12, wherein the second color is white, silver, gold, red, purple, green, blue, gray, black, or a mixed color or gradient color thereof.

19. The lighting device of claim 18, wherein the second color is achieved by the following functional particles:
silver: a titanium dioxide-coated mica flake pearlescent pigment having a particle size D50 of <30 μm;
gold: an iron oxide-coated mica flake pearlescent pigment having a particle size D50 of <30 μm; and
other colorful colors or gradient colors thereof: composite particles of mica powder and an organic dye having a particle size D50 of <20 μm.

20. The lighting device of claim 12, wherein the outer coating causes the LED light source to exhibit a pearlescent appearance in the non-illuminated state of the LED chip.

21. The lighting device of claim 12, wherein the outer coating further comprises an encapsulating glue, and the mass ratio of the functional particles in the encapsulating glue is greater than or equal to 0.1% and less than 10%.

22. The lighting device of claim 21, wherein the encapsulating glue comprises one or more of silica gel, a silicone resin, an epoxy resin, or an acrylate resin, and has a light transmittance of ≥85% after curing.

23. Use of a pearlescent pigment and/or mica powder in preparing an outer coating of an LED light source, wherein the LED light source comprises one or more LED chips, the LED chip is covered with a phosphor material underlying layer, and the outer coating covers the outer side of the phosphor material underlying layer; the phosphor material underlying layer exhibits a first color in a non-illuminated state of the LED chip, and the outer coating causes the LED light source to exhibit a second color different from the first color in the non-illuminated state of the LED chip.
